(19) United States
(12) Patent Application Publication
(10) Pub. No.: US 2026/0190240 A1
(43) Pub. Date: Jul. 2, 2026

(54) METHOD AND SYSTEM FOR MANUFACTURING ELECTRICAL INTERFACE COMPRISING ARRAY OF THIN PINS

(71) Applicant: COMPTAKE TECHNOLOGY INC., NEW TAIPEI CITY (TW)

(72) Inventor: ZHI-WEN FAN, NEW TAIPEI CITY (TW)

(21) Appl. No.: 18/865,339

(22) PCT Filed: May 19, 2023
(86) PCT No.: PCT/CN2023/095237

§ 371 Date: Nov. 13, 2024

Related U.S. Application Data
(60) Provisional application No. 63/344,047, filed on May 20, 2022.

(51) Int. Cl. H05K 3/00; B23H 3/04

(52) U.S. Cl. CPC H05K 3/002; B23H 3/04

(57) ABSTRACT

A processing system is provided which includes a substrate (80); an array of thin pins (81-85) positioned on the substrate; a holding member (12) configured to hold the substrate; an electrolyte tank (21) configured to receive an electrolytic liquid; at least one electrode plate (22-26) positioned in the electrolyte tank; an actuator module (30) configured to move the array of thin pins held on the holding member relative to the electrolyte tank; a metrology module (40) configured to detect positions of the thin pins in the electrolytic liquid and generate measurement data according to a detected result, wherein the movement of the array of thin pins is controlled according to measurement data; and a power supply module (60) configured to apply electrical currents to the electrode plate and the array of thin pins. The processing system can achieve the purpose of mass and rapid production.

### PRIORITY CLAIM

The present application claims the priority of U.S. Provisional Application No. 63/344,047, filed 20 May 2022, the disclosures of which are hereby incorporated by reference herein in their entireties.

### FIELD OF THE INVENTION

Embodiments of present disclosure relate to a system and a method that are used for manufacturing an electrical interface having an array of thin pins.

### BACKGROUND

Nowadays, electrochemical machining (ECM) has become a viable method for machining components in numerous industrial applications, particularly in the manufacture of components with complex structures fabricated from materials that are difficult to cut. ECM is a machining method that able to change the shape of workpiece by eroding materials from workpiece through electrochemical dissolution. In the ECM process a high current is passed between an electrode and the part, through an electrolytic material removal process having a negatively charged electrode (cathode), a conductive fluid (electrolyte), and a conductive workpiece (anode). At the anodic surface, metal on the surface is oxidized and dissolved in the electrolyte, then its shape changed. At the cathode, a reduction reaction occurs, which normally produces hydrogen. The electrolytic fluid carries away the metal hydroxide formed in the process.

The current electrochemical machining process can only process a single workpiece at a time, and thus cannot achieve the purpose of mass and rapid production. It would be desirable to develop methods of electrochemical removal that avoided the above-discussed problems.

### SUMMARY

One aspect of the present disclosure provides a process system. The processing system includes a substrate; an array of thin pins positioned on the substrate; a holding member configured to hold the substrate; an electrolyte tank configured to receive an electrolytic liquid; at least one electrode plate positioned in the electrolyte tank; an actuator module configured to move the array of thin pins held on the holding member relative to the electrolyte tank; a metrology module configured to detect positions of the thin pins in the electrolytic liquid and generate measurement data according to a detected result, wherein the movement of the array of thin pins is controlled according to measurement data; and a power supply module configured to apply electrical currents to the electrode plate and the array of thin pins.

Another aspect of the present disclosure provides an electrical interface, the electrical interface includes a substrate having a lower surface and an edge surrounds the lower surface; and an array of thin pins positioned on the lower surface of the substrate, wherein each thin pins includes a conductive material and is tapered at its lower end that is away from the lower surface of the substrate, wherein the array of thin pins includes: a first thin pin positioned around a center of the lower surface and having a first conical angle at its lower end, a second thin pin positioned adjacent to edge of the substrate and having a second conical angle at its lower end, the second conical angle is smaller than the first conical angle.

Yet another aspect of the present disclosure provides a processing method. The method includes moving an array of thin pins into an electrolytic fluid received in an electrolyte tank; producing measurement data which is related to positions of thin pins in the electrolytic fluid; and when the measurement data meets a preset standard, applying electrical currents to the array of thin pins and an electrode plate positioned in the electrolyte tank so as to change the shape of each of the thin pins through an electrochemical machining process.

The above summary is not intended to describe each illustrated embodiment or every implementation of the present disclosure.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 shows a block diagram of a processing system, in accordance with one or more embodiments of the present disclosure.

FIG. 2 shows a schematic cross-sectional view of a processing system, in accordance with one or more embodiments of the present disclosure.

FIG. 3 shows a schematic view of a reaction zone, in accordance with one or more embodiments of the present disclosure.

FIG. 4 shows a top view of a reaction zone connecting with a power supply module, in accordance with one or more embodiments of the present disclosure.

FIG. 5 shows a top view of an electrical interface before being processed, in accordance with one or more embodiments of the present disclosure.

FIG. 6 shows a side view of an electrical interface of FIG. 5.

FIG. 7 shows a cross-sectional view of one of the thin pins shown in FIG. 6.

FIG. 8 shows a flow chart illustrating a method for processing an electrical interface, in accordance with various aspects of one or more embodiments of the present disclosure.

FIG. 9 shows a schematic view illustrating one stage of a method of performing an electrochemical process at which an array of thin pins is moved to be in contact with a surface of electrolytic liquid.

FIG. 10 shows a schematic view illustrating a relative relationship between tips of the thin pins and the electrolytic liquid in the operation of FIG. 9, in which the tip of one thin pin is not immersed into the electrolytic liquid.

FIG. 11 shows a schematic view illustrating one stage of a method of performing an electrochemical process at which the array of thin pins is placed in a predetermined position in the electrolyte tank.

FIG. 12 shows a schematic view illustrating passivation layers are formed at the interface of the thin pins and the electrolytic liquid after the electrochemical process has been performed for a while.

FIG. 13 shows a schematic view illustrating one stage of a method of performing an electrochemical process at which the array of thin pins is elevated.

FIG. 14 shows a schematic view illustrating one stage of a method of performing an electrochemical process at which the array of thin pins is removed from the electrolytic liquid.

FIG. 15 shows a schematic view illustrating one stage of a method of performing an electrochemical process at which the array of thin pins is rotated to face an image capturing member.

FIG. 16 shows a schematic view illustrating an electrical interface after being processed, in accordance with one or more embodiments of the present disclosure.

FIG. 17 shows a schematic view of a reaction zone, in accordance with one or more embodiments of the present disclosure.

FIG. 18 shows a schematic view of an electrode plate, in accordance with one or more embodiments of the present disclosure.

FIG. 19 shows a schematic view of an electrode plate, in accordance with one or more embodiments of the present disclosure.

FIG. 20 shows a schematic view illustrating one stage of a method of performing an electrochemical process at which the array of thin pins is inserted into an electrode plate in the electrolyte tank.

FIG. 21 shows a flow chart illustrating a method for processing an electrical interface, in accordance with various aspects of one or more embodiments of the present disclosure.

FIG. 22 shows a schematic view illustrating an electrical interface after being processed, in accordance with one or more embodiments of the present disclosure.

FIG. 23 shows a schematic view illustrating an electrical interface before being processed, in accordance with one or more embodiments of the present disclosure.

FIG. 24 shows a flow chart illustrating a method for processing an electrical interface, in accordance with various aspects of one or more embodiments of the present disclosure.

FIG. 25 shows a schematic view illustrating an electrical interface after being processed, in accordance with one or more embodiments of the present disclosure.

### DETAILED DESCRIPTION

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

The terminology used in this specification is intended to describe particular embodiments and is not intended to be limiting. The terms “a,” “an,” and “the” include the plural forms as well, unless clearly indicated otherwise. The terms “comprises,” and/or “includes,” when used in this specification, specify the presence of the stated features, integers, steps, operations, elements, and/or components, but do not preclude the presence or addition of one or more other features, integers, steps, operations, elements, and/or components.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

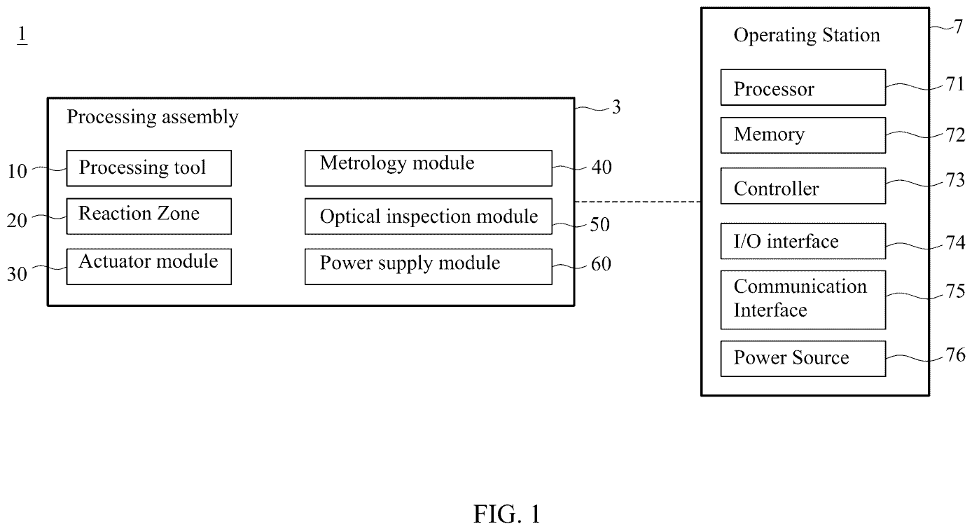

FIG. 1 shows a block diagram of a processing system 1, in accordance with one or more embodiments of the present disclosure. In accordance with some embodiments, the processing system 1 is configured to perform an electrochemical process over a workpiece and includes a processing assembly 3 and an operating station 7. The workpiece to be processed in the present disclosure may be an electrical interface which is used as a probe card in a semiconductor testing process. In some embodiments, the electrical interface includes an array of thin pins with a width of about 5 μm to about 500 μm. It should be appreciated that, while embodiments of present disclosure reveal a system for processing an electrical interface, the disclosure should not be limited thereto. The system and method can be used to process any workpiece at which an oxidation reaction and/or reduction reaction can be activated in an electrochemical process.

The processing assembly 3 is where fabrication takes place and contains a processing tool 10, a reaction zone 20, an actuator module 30, a metrology module 40, an optical inspection module 50, and a power supply module 60. The operating station 7 is used to control and monitor the operation of the processing assembly 3. The operating station 7 may comprise a processor 71, a memory 72, a controller 73, an input/output interface 74 (hereinafter “I/O interface”), a communications interface 75, and a power source 76.

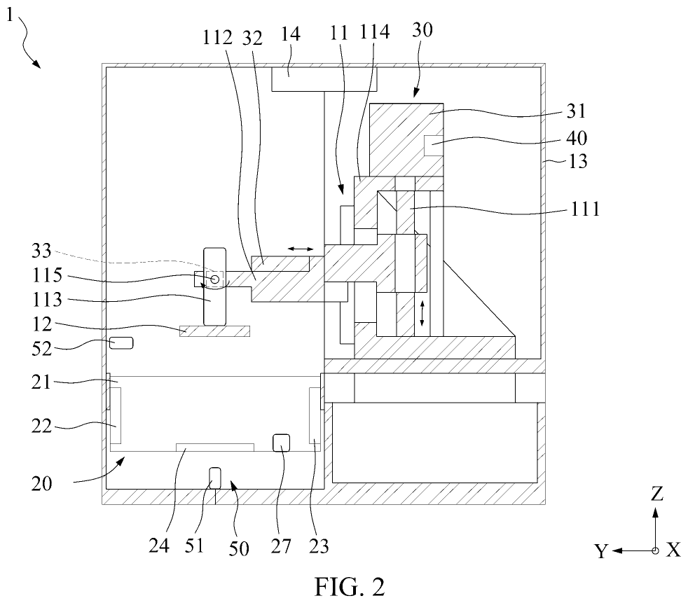

FIG. 2 shows a schematic cross-sectional view of the processing system 1, in accordance with one or more embodiments of the present disclosure. In some embodiments, the processing tool 10 includes a platform 11, a holding member 12, a protection shell 13 and a vitalization member 14. The platform 11 is used to support the holding member 12. As shown in FIG. 2, in one exemplary embodiment, the platform 11 includes a frame 114, a horizontal arm portion 112 and a vertical arm portion 113. An actuator 31 of the actuator module 30 is fixed on a top of a frame 114, and a ball screw 111 is connected to the actuator 31 and extends within the frame 114 for driving a movement of the horizontal arm portion 112 in a vertical direction (Z-axis direction). In addition, an actuator 32 of the actuator module 30 is fixed on the horizontal arm portion 112 to drive a movement of the vertical arm portion 113 in horizontal directions (X-axis and/or Y-axis directions). Furthermore, an actuator 33 of the actuator module 30 is fixed at a pivot 115, which connects the horizontal arm portion 112 and the vertical arm portion 113. The lower end of the vertical arm portion 113 is connected to the holding member 12. When the actuator 33 is driven, the holding member 12 is rotated about the pivot 115. The platform 11 is disposed on the protection shell 13, and the vitalization member 14 is mounted on the top of the protection shell 13 to exhaust gas produced during the electrochemical process.

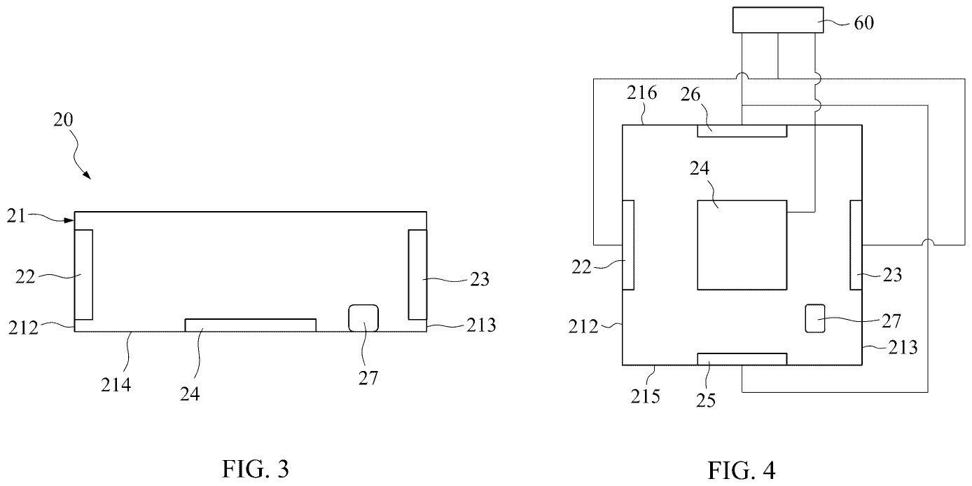

The reaction zone 20 is placed below the holding member 12. FIG. 3 shows a schematic view of the reaction zone 20, and FIG. 4 shows a top view of the reaction zone 20, in accordance with one or more embodiments of the present disclosure, In some embodiments, the reaction zone 20 includes an electrolyte tank 21, a number electrode plates, such as electrode plates 22, 23, 24, 25, and 26. The electrolyte tank 21 may have a rectangular shape with four lateral side walls 212, 213, 215 and 216 and a bottom wall 214. The electrolyte tank 21 define an interior space for receiving electrolytic liquid, and an open end is formed on the top of the electrolyte tank 21. The electrode plates 22, 23, 24, 25, and 26 are positioned in the interior space of the electrolyte tank 21 and connected to the inner surface of the walls of the electrolyte tank 21. Specifically, the electrode plates 22 and 23 are connected to the lateral side walls 212 and 213 which are opposite to each other. The electrode plates 25 and 26 are connected to the lateral side walls 215 and 216 which are opposite to each other. The electrode plate 24 is connected to the bottom wall 214. The electrode plates 22, 23, 24, 25, and 26 are made of material which has anti-rust and anti-corrosion properties. For example, the electrode plates 22, 23, 24, 25, and 26 may be made of stainless steel, but the disclosure should not be limited thereto. More electrode plates which are arranged in orientations different from that of electrode plates 22, 23, 25 and 26 may be disposed in the electrolyte tank 21.

In some embodiments, the electrode plates 22, 23, 24, 25, and 26 are electrically connected to the power supply module 60 to be served as a cathode in the electrochemical process. The power supply module 60 is a DC power source and may include a power pulse generator which is configured to independently control the supply of electrical currents to the electrode plates 22, 23, 24, 25, and 26. For example, the electrode plates 22 and 23 are electrically connected to the power supply module 60 via a conductive line, the electrode plates 25 and 26 are electrically connected to the power supply module 60 via another conductive line, and the electrode plate 24 is electrically connected to the power supply module 60 via yet another conductive line. The pulse pattern of currents applied to the electrode plates 22 and 23 is different from that applied to the electrode plates 25 and 26.

In some embodiments, during the electrochemical process, the power supply module 60 alternately applies electrical currents to the electrode plates 22 and 23 and the electrode plates 25 and 26. For example, the currents applied to the electrode plates 22 and 23 are on OFF state, while the currents applied to the electrode plates 25 and 26 are on ON state. The pulse frequency of the electrical current applied to the electrode plate 24 may be different from that of the electrode plates 22, 23, 25 and 26. In some embodiments, the pulse frequency of the electrical currents applied to the electrode plate 24 is less than that applied to electrode plates 22, 23, 25 and 26. In some other embodiments, the power supply module 60 constantly applies electrical currents to the electrode plate 24 during the electrochemical process.

In some embodiments, as shown in FIG. 2, the reaction zone 20 further includes a transducer 27. The transducer 27 is positioned in the interior space of the electrolyte tank 21. The transducer 27 may be an ultrasound transducer which converts electrical energy into mechanical (sound) energy and back again, based on the piezoelectric effect. With the transducer 27, a vibration of the electrolytic liquid in the electrolyte tank 21 can be generated during the electrochemical process.

Referring to FIG. 2, the optical inspection module 50 is configured to capture images of the workpiece in the processing system 1 before, during or after the electrochemical process. In some embodiments, the optical inspection module 50 includes a number of image capturing members, such as image capturing member 51 and 52.

The image capturing member 51 is disposed below the reaction zone 20 and is configured to capture image of the workpiece processed in the reaction zone 20. In case where the electrode plate 24 is disposed on the bottom wall 214 (FIG. 3) of the electrolyte tank 21, the electrode plate 24 is positioned between the image capturing member 51 and the holding member 12 (or a workpiece held by the holding member 12). In some embodiments, to facilitate the inspection of the workpiece by the image capturing member 51, the electrode plate 24 is made of transparent conducting oxide, such as indium tin oxide (ITO), fluorine doped tin oxide (FTO), niobium doped anatase TiO2 (NTO), or doped zinc oxide.

The image capturing member 52 is positioned above the reaction zone 20 and is configured to capture image of the workpiece after it is removed from the reaction zone 20. In some embodiments, the image capturing member 52 is fixed on a side wall of the protection shell 13 and is positioned higher than the reaction zone 20. In some embodiments, the light incident surface of the image capturing member 52 is vertically arranged (i.e., arranged parallel to Z-axis.) The data related to images captured by the image capturing member 51 and the image capturing member 52 may be transmitted to the operating station 7 for further analysis.

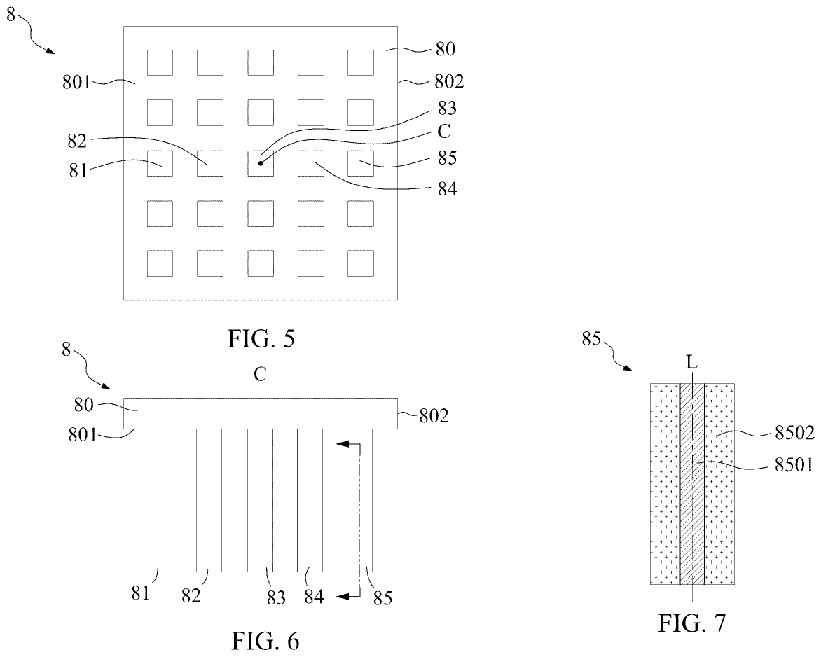

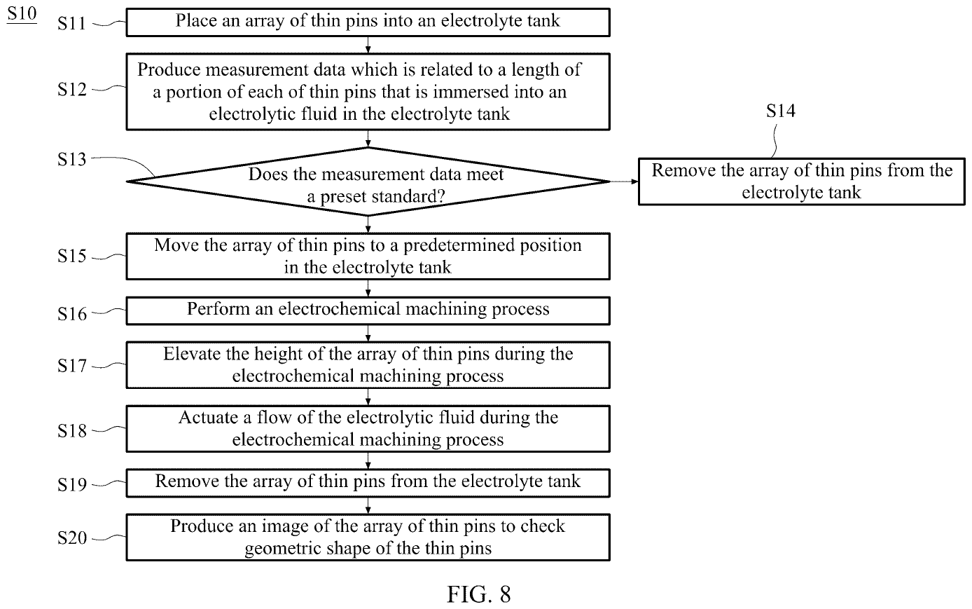

Referring FIGS. 5-7, in accordance with some embodiments of present disclosure, the workpiece to be processed in the processing system 1 is an electrical interface 8. The electrical interface 8 is a part of a probe card used in a semiconductor testing tool (not shown in figures). In some embodiments, the electrical interface 8 includes a substrate 80 and an array of thin pins, such as thin pins 81, 82, 83, 84 and 85. The substrate 80 has a lower surface 801 and four edges 802 surrounds the lower surface 801. The thin pin 83 is located at the center C of the lower surface 801, and the thin pins 81 and 85 are located adjacent to the two edges 802. The thin pin 82 is positioned between the thin pins 81 and 83, and the thin pin 84 is positioned between the thin pins 83 and 85. The thin pins 81, 82, 83, 84 and 85 may be arranged in a line that is perpendicular to the edges 802 or inclined relative to the edges, or may be arranged along a diagonal line of the lower surface 801.

The thin pins 81, 82, 83, 84 and 85 are arranged in a matrix pattern on the lower surface 801 of the substrate 80. While, in the present embodiment shown in the figures, there are 25 thin pins arranged in a 5×5 matrix on the substrate 80, the disclosure should not be limited to this embodiment. The electrical interface can accommodate any number of thin pins. In one exemplary embodiment, there are 1200 thin pins disposed on the substrate 80. The thin pins 81, 82, 83, 84 and 85 can be fixed on the lower surface 801 of the substrate 80 through any suitable method. For example, the thin pins 81, 82, 83, 84 and 85 can be fixed on the substrate by welding, bonding, fastening, etc.

In some embodiments, at least one of thin pins 81, 82, 83, 84 and 85 includes composite structure. For example, the thin pin 85 extends along a longitudinal axis L that is perpendicular to the lower surface 801 of the substrate 80. The thin pin 85 includes a inner portion 8501 and a outer portion 8502. The outer portion 8502 is located farther away from the longitudinal axis L than the inner portion 8501. The inner portion 8501 and the outer portion 8502 are formed of different conductive materials. In some embodiments, the electric conductivity of the outer portion 8502 is greater than the electric conductive of the inner portion 8501. Additionally or alternatively, the hardness of the outer portion 8502 is smaller than the hardness of the inner portion 8501. With such arrangement, the thin pin 85 offers an optimal electrical conductivity without compromising its structural strength. In one exemplary embodiment, the inner portion 8501 includes tungsten (W), and the outer portion 8502 includes molybdenum (Mo). The substrate 80 may be made of conductive material such as aluminum, stainless steel, or the like. The thin pins 81, 82, 83, 84 and 85 are electrically connected to the substrate 80. When the substrate 80 is connected to the power supply module 60, the thin pins 81, 82, 83, 84 and 85 are energized and served as anodes in the electrochemical process.

Referring to FIG. 2, the metrology module 40 is configured to monitor at least one parameter in the processing system 1 in real-time. In some embodiment, the metrology module 40 is positioned in the processing assembly 3 and can provide real-time monitoring of a movement of the holding member 12 (or the electrical interface 8 when it is mounted on the holding member 12). For example, the metrology module 40 is connected to the actuator 31 which used to drive a movement of the holding member 12 in Z-axis direction, and include a detector that can be used to detect a force change of the actuator 31. The metrology module 40 may include a strain gauge to measure stretches or compresses of the ball screw 111. Alternatively, the metrology module 40 may include a pressure gauge to measure a pressure applied on the ball screw 111 by the actuator 31. Historical data of the force change which represents a normal and successful condition is recorded in the memory 72 of the operating station 7. Abnormal diagnosis can be performed by the processor 71 of the operation station 7 by historical data comparison and analysis.

Referring back to FIG. 1, the processor 71 may comprise any processing circuitry operative to process the measurement data generated by the metrology module 40 to determine whether an abnormal occur. In various aspects, the processor 71 may be implemented as a general purpose processor, a chip multiprocessor (CMP), a dedicated processor, an embedded processor, a digital signal processor (DSP), a network processor, an input/output (I/O) processor, a media access control (MAC) processor, a radio baseband processor, a co-processor, a microprocessor such as a complex instruction set computer (CISC) microprocessor, a reduced instruction set computing (RISC) microprocessor, and/or a very long instruction word (VLIW) microprocessor, or other processing device.

In some embodiments, the memory 72 may comprise any machine-readable or computer-readable media capable of storing data, including both volatile/non-volatile memory and removable/non-removable memory which is capable of storing one or more software programs. The software programs may contain, for example, applications, user data, device data, and/or configuration data, archival data relative to the environmental parameter or combinations therefore, to name only a few. The software programs may contain instructions executable by the various components of the operating station 7. For example, memory 72 may comprise read-only memory (ROM), random-access memory (RAM), dynamic RAM (DRAM), disk memory (e.g., floppy disk, hard drive, optical disk, magnetic disk), or card (e.g., magnetic card, optical card), or any other type of media suitable for storing information. In one embodiment, the memory 72 may contain an instruction set stored in any acceptable form of machine readable instructions. The instruction set may include a series of operations after an abnormality is found in the processing system 1 based on the signals obtained by the metrology module 40.

The controller 73 is configured to control one or more elements of the processing system 1. In some embodiments, the controller 73 is configured to drive the movement of the holding member 12 of the processing tool 10, and the application of electrical current to the electrical interface 8 and the electrode plates 22, 23, 24, 25, and 26. The controller 73 includes a control element, such as a microcontroller. The controller 73 issues control signals to the actuator module 30 in response to a command from the processor 71.

In some embodiments, the I/O interface 74 may comprise any suitable mechanism or component to at least enable a user to provide input to the operating station 7 or to provide output to the user. For example, the I/O interface 74 may comprise any suitable input mechanism, including but not limited to, a button, keypad, keyboard, click wheel, touch screen, or motion sensor. In some embodiments, the I/O interface 74 may comprise a capacitive sensing mechanism, or a multi-touch capacitive sensing mechanism (e.g., a touch screen). In some embodiments, the I/O interface 74 may comprise a visual peripheral output device for providing a display visible to the user. For example, the visual peripheral output device may comprise a screen such as, for example, a Liquid Crystal Display (LCD) screen.

In some embodiments, the communications interface 75 may comprise any suitable hardware, software, or combination of hardware and software that is capable of coupling the operating station 7 to one or more networks and/or additional devices (such as, for example, the actuator module 30.) The communications interface 75 may be arranged to operate with any suitable technique for controlling information signals using a desired set of communications protocols, services or operating procedures. The communications interface 75 may comprise the appropriate physical connectors to connect with a corresponding communications medium, whether wired or wireless. In some embodiments, the operating station 7 may comprise a system bus that couples various system components including the processor 71, the memory 72, the controller 73 and the I/O interface 74. The system bus can be any custom bus suitable for computing device applications.

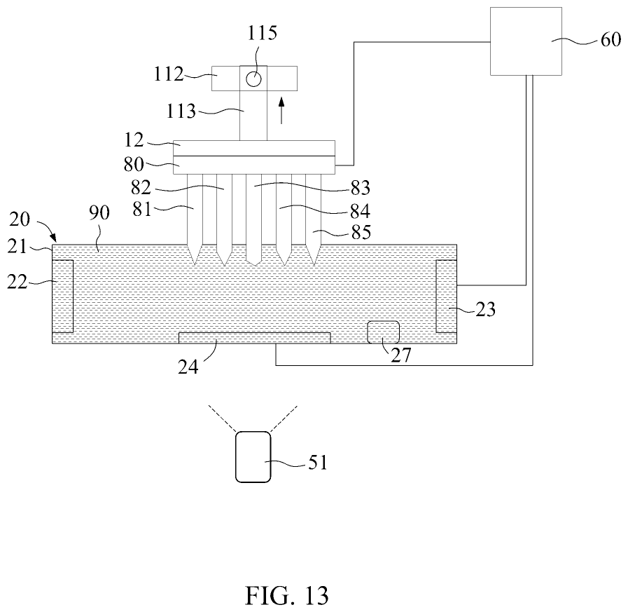

FIG. 8 shows a flow chart illustrating a method S10 for processing an electrical interface 8, in accordance with various aspects of one or more embodiments of the present disclosure. For illustration, the flow chart will be described along with the drawings shown in FIGS. 1, 2 and 9-15. Some of the described stages can be replaced or eliminated in different embodiments.

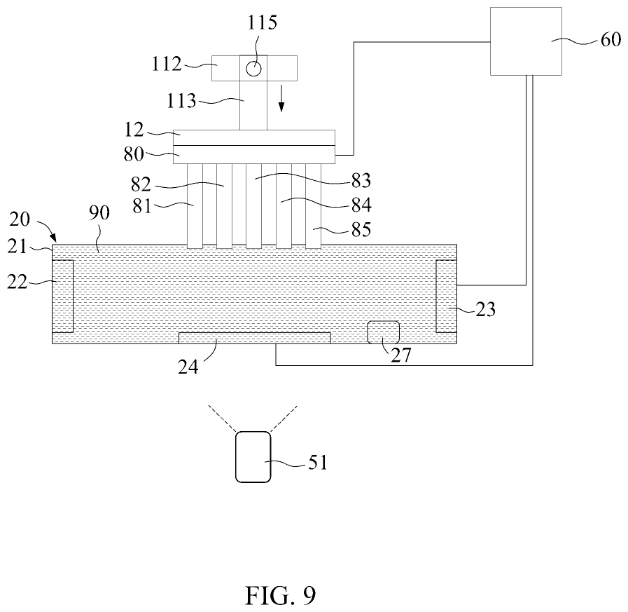

In step S11, an array of thin pins is placed into an electrolyte tank. In some embodiments, the thin pins, such as thin pins 81, 82, 83, 84, and 85, are first fixed onto substrate 80. As shown in FIG. 9, the substrate 80, along with the thin pins 81, 82, 83, 84, and 85, is then mounted onto holding member 12 (FIG. 2), with its lower surface 801 facing downwards. Following the securement of substrate 80 onto holding member 12, the actuator 31 (FIG. 2) is engaged, driving the holding member 12 downwards and moving the thin pins into electrolyte tank 21.

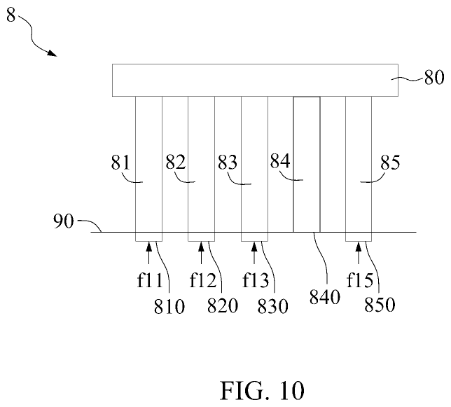

In step S12, a measurement data which is related to a position of the thin pins in an electrolytic liquid 90 received in the electrolyte tank are produced. In some embodiments, the metrology module 40, which is mounted on the actuator 31, produces the measurement data by measuring the force generated during the downward movement of thin pins 81, 82, 83, 84, and 85. Upon contact with the electrolyte surface, surface tensions generates upward resistance which is detected to determine whether all the thin pins are in contact with the electrolyte surface. As shown in FIG. 10, an abnormal situation may arise where the tips of some thin pins, such as tip 840 of thin pin 84, fail to insert into the electrolyte surface as expected. In such a case, the detector will only detect the surface tensions f11, f12, f13 and f15 applied to the tips 810, 820, 830 and 850 of the other thin pins 81, 82, 83, and 85. If the measurement data fails to meet the preset standard upon comparison with historical data performed in step S13, step S14 proceeds, which involves removing the array of thin pins 81, 82, 83, 84, and 85 from electrolyte tank 21. Following removal, the thin pins may be adjusted to a uniform height, for instance by grinding or compressing them. If the thin pins cannot be adjusted properly, they may be discarded.

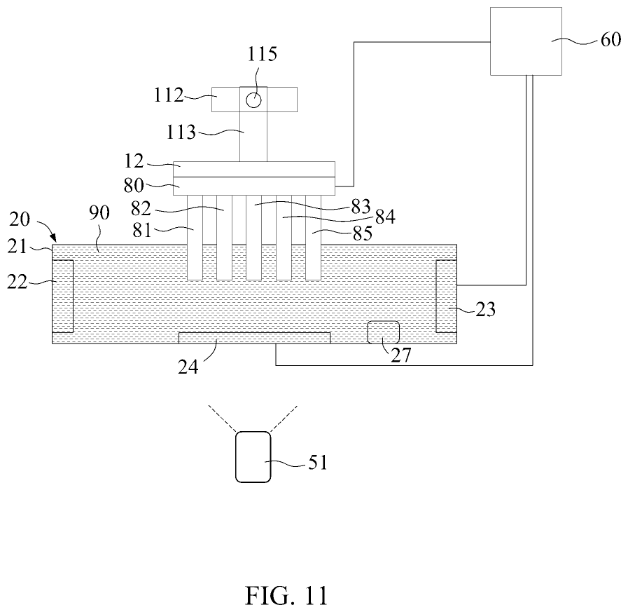

If no abnormality is found, the method continues to step S15, in which the array of thin pins 81, 82, 83, 84, and 85 are move to a predetermined position in the electrolyte tank 21, as shown in FIG. 11. The predetermined distance above is a preset distance of the thin pins 81, 82, 83, 84, and 85 under the surface of the electrolytic liquid 90. This distance can be determined through experience, or by analyzing historical data generated in the previous process. Alternatively, the immersion distance can be determined according to the largest chamfer angle (i.e., smallest conical angle) formed in the diameter direction of the thin pins. In the embodiment where the thin pins are processed by immersion method (the thin pins and electrode plate are stationary), the immersion distance of the thin pins 81, 82, 83, 84, and 85 is determined based on the largest chamfer angle (i.e., smallest conical angle) formed in the diameter direction of the thin pins and may be in a range of about 5 μm to about 5 mm. In the embodiment where the thin pins are processed by dynamic drawing method, the immersion distance is determined by the length of the inclined edge of the thin pins. The longer length of the inclined edge (i.e., the smaller conical angle), the greater the immersion distance is set.

In step S16, an electrochemical machining process is performed. During the ECM process, the power supply module 60 applies a direct current (DC) to the thin pins 81, 82, 83, 84, and 85 and the electrode plates 22, 23, 24, 25, and 26 to form a bias between the thin pins 81, 82, 83, 84, and 85 and the electrode plates 22, 23, 24, 25, and 26. In some embodiments, a positive bias is applied to the electrode plates 22, 23, 24, 25, and 26, and a negative bias is applied to the holding member 12 so that the thin pins 81, 82, 83, 84, and 85 served as an anode and the electrode plates 22, 23, 24, 25, and 26 is served as a cathode. Therefore, an oxidation reaction occurs at the surface of the thin pins 81, 82, 83, 84, and 85 when the electrons flows from the thin pins 81, 82, 83, 84, and 85 to the electrode plates 22, 23, 24, 25, and 26 through the electrolytic liquid 90. In general, the power supply module 60 may be a constant-voltage power supply or a constant-current power supply and is capable of providing power between about 0 Watts and 100 Watts, a voltage between about 1V and 60V, and a current between about 0 amps and about 200 amps. In addition, the power supply module 60 may apply constant current or a periodic current pulse. The frequency of the periodic current pulse is lower than 2.5 KHz. The power supply module 60 may be a high-frequency pulse power supply, equipped with three power output modes of high-frequency square wave/sine wave/DC supply. With the high-frequency pulse power supply, the ion migration speed in the dissociation reaction can be changed by controlling the power output modes. However, the particular operating specifications of the power supply may vary according to application. In embodiments where the thin pins 81, 82, 83, 84, and 85 are formed with different conductive material which having different redox potential, the voltage applied to the thin pins 81, 82, 83, 84, and 85 is greater than the largest redox potential of the thin pins 81, 82, 83, 84, and 85.

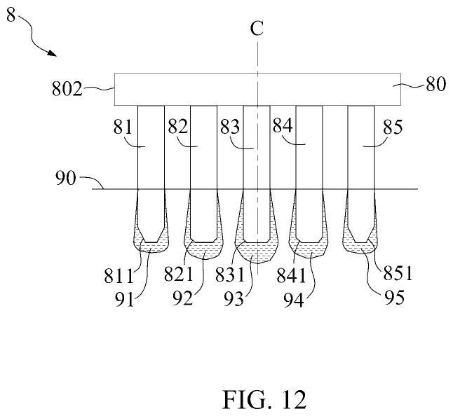

In some embodiments, as shown in FIG. 12, during the ECM of thin pins 81, 82, 83, 84, and 85, the thickness of the thin pins is gradually decreased and passivation layers 91, 92, 93, 94 and 95 might form around the lower end of the thin pins 81, 82, 83, 84, and 85 in the form of oxides. These layers will suppress material removal and reduce surface finish of the thin pins. It has been observed that the thickness of the passivation layer formed on the thin pins 83 at the center C of the substrate 80 is greater than that formed on the thin pins 81 and 85 at the edge 802 of the substrate 80. As a result, the oxidation reaction of the thin pin 83 located at the center of the substrate 80 is slower, leading to lower material removal rate, compared to the thin pins 81 and 85 located at the edge 802 of the substrate 80. Therefore, as shown in FIG. 12, the lower ends of the thin pins 81, 82, 83, 84, and 85 are chamfered with different angles. In one exemplary embodiment, chamfers 811, 821, 831, 841 and 851 are formed at the lower ends of the thin pins 81, 82, 83, 84, and 85. The angle formed between the chamfer 831 of the thin pin 83 and its adjacent surface is greater than the angle between the chamfer 821 of the thin pins 82 and its adjacent surfaces, and the angle between the chamfer 821 of the thin pin 82 and its adjacent surface is greater than the angle between the chamfer 811 of the thin pin 81 and its adjacent surface.

In some embodiments, the appearance of the thin pins 81, 82, 83, 84, and 85 during processing is inspected by the image capturing member 51. The images generated by the image capturing member 51 are transmitted to the operating station 7 for analysis. If the image analysis result deviates from expected criteria, the operating station 7 will adjust the process parameters to optimize the appearance of the thin pins. The adjustable process parameters may include, but are not limited to, changing the applied voltage, adjusting the moving speed or pattern of the thin pins, modifying the temperature of the electrolytic liquid 90, and changing the vibration frequency of the transducer 27, among others.

In step S17, the height of the thin pins 81, 82, 83, 84, and 85 are changed during the electrochemical machining process. In some embodiments, the thin pins 81, 82, 83, 84, and 85 are processed through electrochemical machining process accompanying with dynamic drawing method in which the thin pins are gradually lifted until they are removed from the surface of the electrolytic liquid 90. The movement speed of the thin pins 81, 82, 83, 84, and 85 may remain constant as they move upward, or it may vary. For example, the thin pins 81, 82, 83, 84, and 85 may move slower in the early stages of upward movement and faster in the later stages. In other words, the closer the thin pins 81, 82, 83, 84, and 85 are to the surface of the electrolytic liquid 90, the slower their movement.

In another embodiment, the thin pins 81, 82, 83, 84, and 85 are initially moved upward without disengaging the lower end from the surface of the electrolytic liquid 90, then moved downward. This up-and-down movement can be repeated multiple times until the entire electrochemical machining process is complete, and can be performed simultaneously with the aforementioned speed changes.

In some embodiments, the electrochemical machining process occurs during the downward movement of the lower end of the thin pins 81, 82, 83, 84, and 85 after they contact the surface of the electrolytic liquid 90 at a slow speed. However, it should be noted that the present disclosure is not limited to this embodiment. In other embodiments, the thin pins 81, 82, 83, 84, and 85 may remain stationary during the electrochemical machining process, and may be removed from the electrolyte immediately after the completion of the electrochemical machining process.

In some embodiments, the speed at which the thin pins 81, 82, 83, 84, and 85 move is predetermined based on previous successful process parameters. Alternatively, the speed at which the thin pins move can be determined based on parameters which are monitored in real-time, including but not limited to: changes in the power transfer energy between the cathode and the anode, changes in the power output waveform, and changes in the moving speed in the axial direction. In some embodiments, step S17 is omitted. The thin pins 81, 82, 83, 84, and 85 are processed through electrochemical machining process accompanying with immersion method in which the thin pins are kept stationary for a predetermined time period and is lifted to leave the electrolytic liquid 90 after the completion of electrochemical machining process.

In step S18, a flow of electrolytic liquid 90 is actuated during the electrochemical machining process. In some embodiments, the flow of electrolyte can be actuated by the up-and-down movement of the thin pins 81, 82, 83, 84, and 85, as described previously. In other embodiments, the flow of electrolytic liquid 90 can be initiated by a transducer 27 positioned within the electrolyte tank 21. The transducer 27 can produce vibrations at a fixed or varied frequency to induce the flow of electrolytic liquid 90 within the electrolyte tank 21. In yet other embodiments, the flow of electrolytic liquid 90 can be produced by changing the electric field generated by the application of direct current. For example, as shown in FIG. 4, the power supply module 60 can first supply electrical currents to the electrode plates 22 and 23 for a first time period, after which the supply of electrical current can be stopped, and then the power supply module 60 can supply electrical currents to the electrode plates 25 and 26 for a second time period. The second time period may immediately follow the first time period. In some embodiments, the flow of electrolytic liquid 90 within the electrolyte tank can minimize or eliminate the formation of a passivation layer at the surface of the thin pins, thereby improving the consistency in appearance of adjacent thin pins.

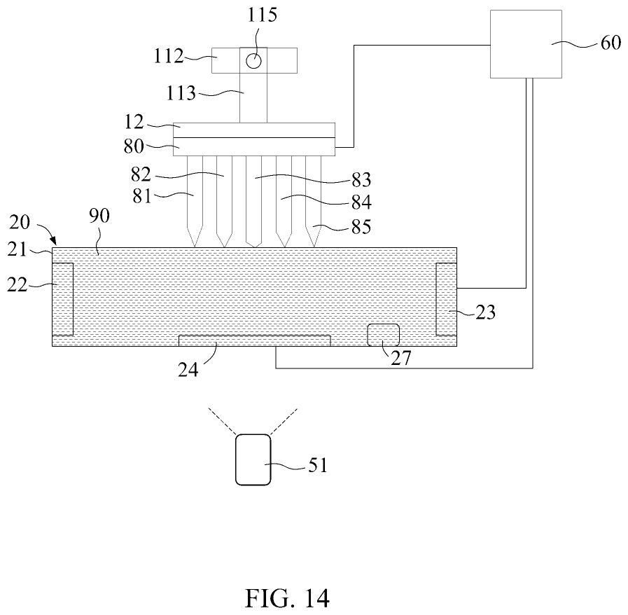

In step S19, the array of the thin pins 81, 82, 83, 84, and 85 is removed from the electrolyte tank 21. In some embodiments, as shown in FIG. 14, after the completion of the ECM process, the thin pins 81, 82, 83, 84, and 85 are removed from the electrolyte tank 21, and the supply of electrical currents to the thin pins 81, 82, 83, 84, and 85 and the electrode plates 22, 23, 24, 25, and 26 is stopped.

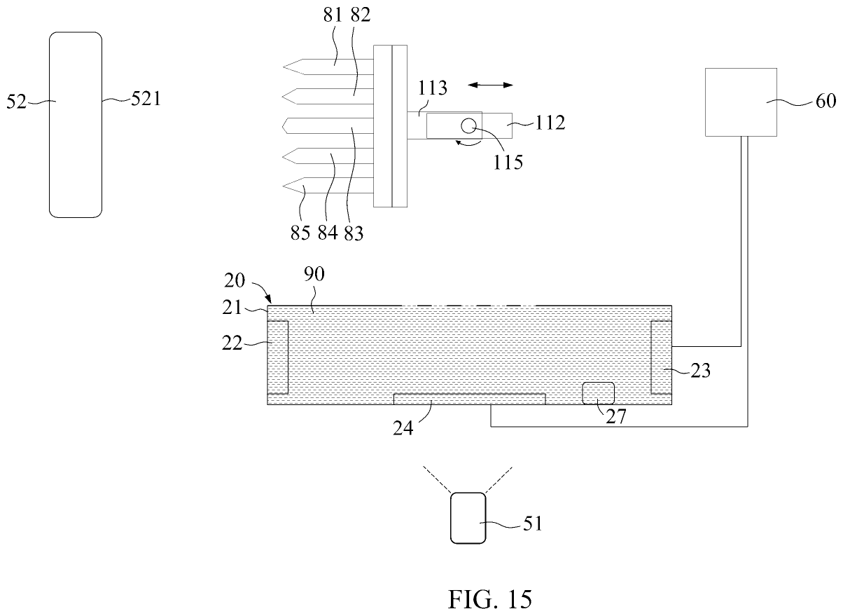

In step S20, an image of the array of thin pins 81, 82, 83, 84, and 85 is produced to check geometric shape of the thin pins 81, 82, 83, 84, and 85. In some embodiments, upon completion of the ECM process, the images of the processed thin pins 81, 82, 83, 84, and 85 are captured by the image capturing member 52 and transmitted to operating station 7 for storage. The data associated with the image of the processed product is then matched with the process parameters used during the manufacturing process to optimize subsequent process parameters. In some embodiments, the processed thin pins can be photographed in situ, without the need to remove them from the holding member 12. For example, as shown in FIG. 15, the holding member 2 can be rotated 90 degrees around the pivot 115, allowing the thin pins to face a light incident surface 521 of the image capturing member 52 directly. Additionally, the distance between the holding member 2 and the image capturing member 52 may be adjusted by moving the horizontal arm portion 112 to achieve proper focus of the thin pins.

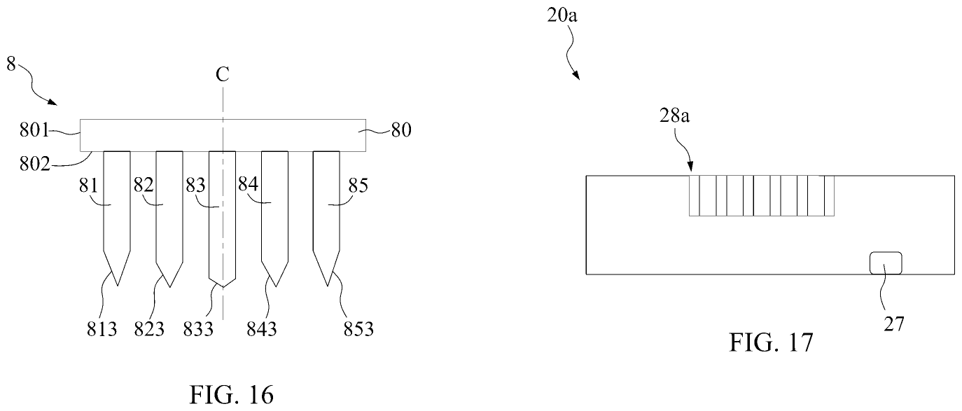

FIG. 16 shows a schematic view illustrating an electrical interface 8 after being processed, in accordance with one or more embodiments of the present disclosure. In this figure, the difference in conical angles of the thin pins is deliberately exaggerated for descriptive purposes. In some embodiments, each thin pins is tapered at its lower end that is away from the lower surface 801 of the substrate 80. Due to the formation of the passivation layers during the ECM process, the conical angles of the thin pins closer to the center C of the lower surface 801 is greater than that of the thin pin farther away from the center C of the lower surface 801. For example, the thin pin 83 which is positioned around the center C of the lower surface 801 has a first conical angle at its lower end, and the thin pin 81 which is positioned adjacent to edge 802 of the substrate 80 has a second conical angle at its lower end. The second conical angle is smaller than the first conical angle. Inconsistent conical angles do not directly affect the performance of the electrical interface as long as the difference in length between adjacent pins is within tolerance. Compared with traditional electrical interface, the electrical contacts (aluminum (copper) pad/copper pillar/bump) of the electrical interface in this exemplary embodiment are smaller in area and larger in number (i.e., higher gaps density). Therefore, the electrical interface in this exemplary embodiment can fully meet the strict requirements of the advanced packaging technology.

FIG. 17 shows a schematic view of a reaction zone 20a, in accordance with one or more embodiments of the present disclosure. The components in FIG. 17 that use the same reference numerals as the components of FIG. 3 refer to the same components or equivalent components thereof. For the sake of brevity, it will not be repeated here. Differences between the reaction zone 20a and the reaction zone 20 include the electrode plates 22, 23, 24, 25 and being replaced by the electrode plates 28a.

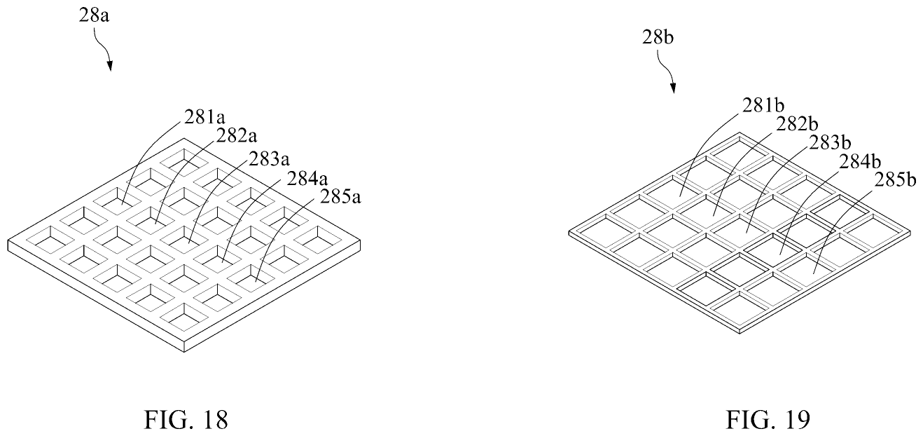

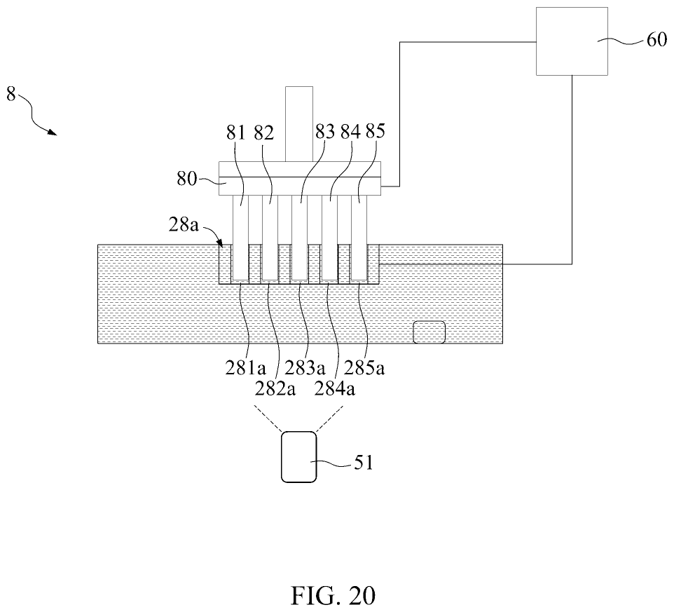

In some embodiments, as shown in FIG. 18, the electrode plate 28a includes a number of through holes, and each of the through holes define a processing region. The processing regions, such as processing regions 281a, 282a, 283a, 284a, 285a, are arranged corresponding to the thin pins 81, 82, 83, 84 and 85 of the electrical interface 8. During the ECM process, the thin pins 81, 82, 83, 84 and 85 are respectively inserted into the processing regions 281a, 282a, 283a, 284a, 285a. In some embodiments, electrical field in each of the processing regions 281a, 282a, 283a, 284a, 285a is independently controlled by the power supply module 60. Therefore, the electrical current density applied to two neighboring processing regions may be different. The electrode plate 28a may be fixed at the upper opening of the electrolyte tank 21 by suitable fixing means and electrically connected to the power supply module 60.

In some embodiments, the electrode plate 28a has a thickness which is equal to or greater than a length of the portion of the thin pins that is immersed into the electrolytic liquid. In this embodiment, the portion of the thin pin submerged in the electrolytic liquid is completely surrounded the processing regions, which increases the oxidation reaction rate. However, it should be noted that the present disclosure is not limited to this embodiment. In another embodiment, as illustrated in FIG. 19, the electrode plate 28b has a relatively thin thickness, and when the thin pins are immersed in the electrolytic liquid, they pass through the processing regions, such as processing regions 281b, 282b, 283b, 284b, 285b, of the electrode plate 28b.

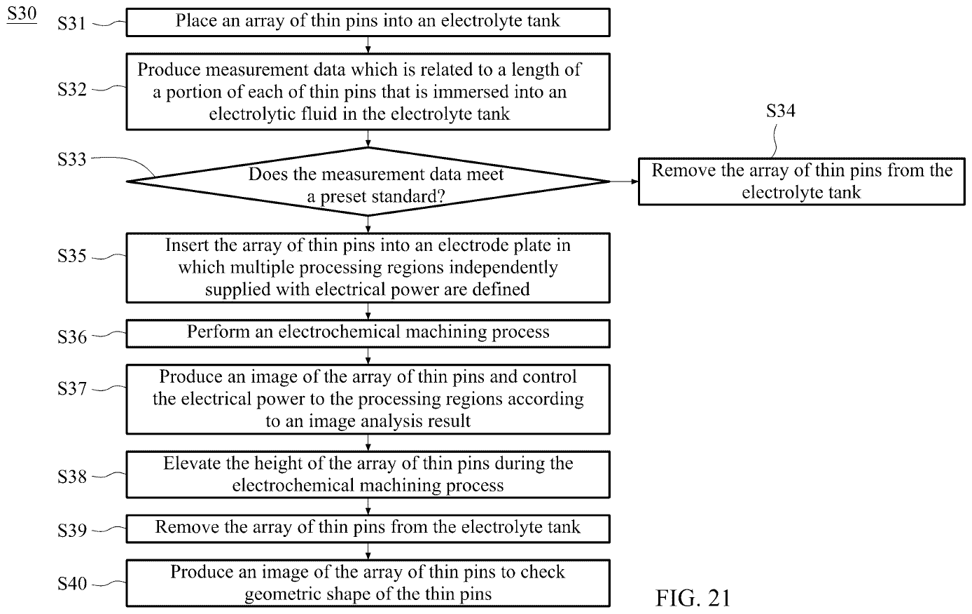

FIG. 21 shows a flow chart illustrating a method S30 for processing an electrical interface 8 with the use of electrode plates 28a, in accordance with various aspects of one or more embodiments of the present disclosure. In method S30, steps S31, S33, S34, S36, S38, S39 and S40 are similar to steps S11, S13, S14, S16, S18, S19 and S20, and therefore will not be repeated here.

In step S32, in addition to the mechanism described in step S12 where resistance measurement is used to determine whether all of the thin pins are immersed in the electrolytic liquid 90 at the same time, it is also possible to detect the immersion status of the thin pins by monitoring the current changes in each processing regions of the electrode plate 28a. Since the power is applied independently to each processing region, an electrical connection will be established between the energized thin pin and the corresponding processing region when the thin pin enters. Therefore, by detecting the current of the processing region, it is possible to estimate whether the thin pin has been successfully immersed into the electrolytic liquid.

In step S35, the array of thin pins is inserted into the processing regions of the electrode plate 28a. The lower ends of the thin pins which are away from the lower surface of the substrate 80 may be located within or below the processing regions of the electrode plate 28a depending on the desired geometric shape of the final product. However, it will be appreciated that many variations and modifications can be made to embodiments of the disclosure. In some embodiments, the electrode plates 28a or 28b are placed within the electrolytic liquid and keep a certain distance from the surface of the electrolytic liquid. The lower ends of the thin pins are immersed into the electrolytic liquid but do not inserted into the processing regions of the electrode plates 28a or 28b.

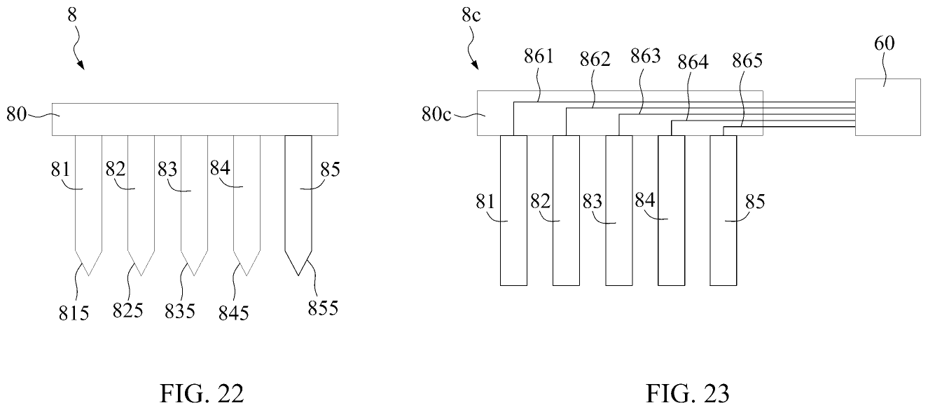

In step S37, after analyzing the image generated by the image capturing member 51, if it is found that the appearance of some thin pins does not meet the expected standard, mechanism described in step 17 may be taken. Additionally, the current intensity in the processing regions which receive the thin pins can be adjusted to adjust their appearance so as to increase or decrease the oxidation reaction rate of the thin pins. By independently controlling the oxidation reaction rate of each thin pin during the processing, the resulting thin pins exhibit a higher degree of similarity in appearance compared to thin pins shown in FIG. 16. For example, as shown in FIG. 22, the lower ends 815, 825, 835, 845 and 855 of the thin pins processed using this method exhibit highly similar conical angles, which further enhances the uniformity and consistency of the final product.

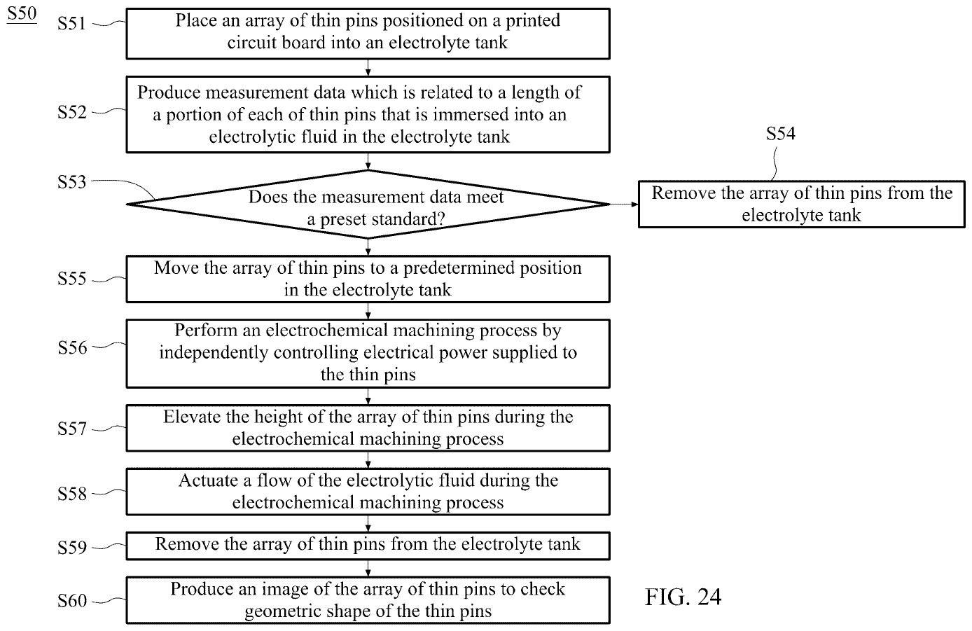

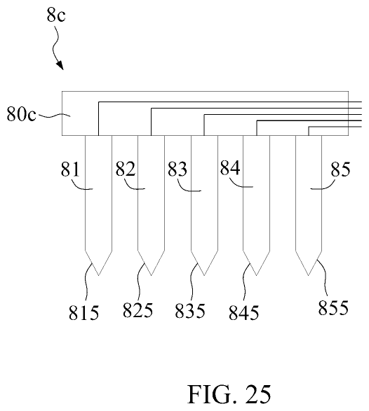

FIG. 23 shows a schematic view of an electrical interface 8c connected with the power supply module 60, in accordance with one or more embodiments of the present disclosure. The components in FIG. 23 that use the same reference numerals as the components of FIG. 6 refer to the same components or equivalent components thereof. For the sake of brevity, it will not be repeated here. Differences between the electrical interface 8c and the electrical interface 8 include the substrate 80 being replaced by the substrate 80c. In some embodiments, the substrate 80c is a printed circuit board with a number of conductive paths, such as conductive paths 861, 862, 863, 864, and 865, formed thereon. In some embodiments, each of thins pins 81, 82, 83, 84, and 85 are respectively electrically connected to one conductive paths 861, 862, 863, 864, and 865 of the substrate 80c. However, it should be noted that the present disclosure is not limited to this embodiment. In another embodiment, two or more thin pins can be connected to the same electrical conductive path and having the same electrical current intensity during the ECM process.

FIG. 24 shows a flow chart illustrating a method S50 for processing an electrical interface 8c with the use of the reaction zone 20, in accordance with various aspects of one or more embodiments of the present disclosure. In method S50, steps S51, S53, S54, S55, S57, S58, S59 and S60 are similar to steps S11, S13, S14, S15, S18, S19 and S20, and therefore will not be repeated here.

In step S52, in addition to the mechanism described in step S12 where resistance measurement is used to determine whether all of the thin pins are immersed in the electrolytic liquid 90 at the same time, it is also possible to detect the immersion status of the thin pins by monitoring the current changes in each of thin pins 81, 82, 83, 84, and 85. Since the power is applied independently to each thin pins 81, 82, 83, 84, and 85, an electrical connection will be established between the energized thin pins and the electrode plates when the thin pins are in contact with the electrolytic liquid. Therefore, by detecting the current of the thin pins 81, 82, 83, 84, and 85, it is possible to identify which thin pin has not immersed into electrolytic liquid. The data collected in step S 52 can be utilized in step S54, in which the identified thin pin are further processed.

In step S56, electrical power is supplied to the thin pins to perform an electrochemical machining process. In some embodiments, the power supply module 60 applies electrical currents to the thin pins 81, 82, 83, 84, and 85 via the conductive paths 861, 862, 863, 864, and 865, such that the electrical current intensity of the thin pins 81, 82, 83, 84, and 85 can be independently controlled during the ECM process. The current intensity of the thin pins 81, 82, 83, 84, and 85 can be determined according to the matching result of previous product appearance and applied parameters. For example, if the image analysis result in the previous round of product represents that the conical angle of the thin pin 83 is greater than that of the thin pin 81, the power supply module 60 may be controlled to supply a higher current intensity to the thin pin 83 while supply a lower current intensity to the thin pin 81 to enhances the uniformity and consistency of the final product.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A processing system, comprising:
a substrate;
an array of thin pins positioned on the substrate;
a holding member configured to hold the substrate;
an electrolyte tank configured to receive an electrolytic liquid;
at least one electrode plate positioned in the electrolyte tank;
an actuator module configured to move the array of thin pins held on the holding member relative to the electrolyte tank;
a metrology module configured to detect positions of the thin pins in the electrolytic liquid and generate measurement data according to a detected result, wherein the movement of the array of thin pins is controlled according to measurement data; and
a power supply module configured to apply electrical currents to the electrode plate and the array of thin pins.

2. The processing system of claim 1, wherein the metrology module is used to measure a friction force generated between the thin pins and the electrolytic fluid or to measure electrical currents that flow through the thin pins.

3. The processing system of claim 1, further comprising: an image capturing member positioned below a bottom surface of the electrolyte tank, wherein the image capturing member is configured to monitor a change in the shape of the array of thin pins during an electrochemical machining process.

4. The processing system of claim 3, wherein the electrode plate is positioned between the image capturing member and the array of thin pins during an electrochemical machining process, wherein the electrode plate comprises transparent conducting oxide.

5. The processing system of claim 1, further comprising an image capturing member configured to check the shape of the array of thin pins after an electrochemical machining process.

6. The processing system of claim 1, wherein the substrate comprises a printed circuit board electrically connected to the power supply module, wherein at least two of the thin pins are electrically connected to two conductive paths formed in the printed circuit board, and the power supply module applies electrical currents to the two of the thin pins via the two conductive paths.

7. The processing system of claim 1, further comprising two pairs of electrode plates, wherein the electrolyte tank comprises a plurality of lateral side walls, and each pair of the electrode plates is positioned at two of the lateral side walls that are arranged opposite to each other.

8. The processing system of claim 1, wherein the electrode plate is positioned adjacent to an upper opening of the electrolyte tank and defining at least two different processing regions, wherein the power supply module independently controls the electrical currents applied to each of the processing regions.

9. The processing system of claim 1, further comprising a transducer positioned in the electrolyte tank and configured to create a vibration of the electrolytic liquid in the electrolyte tank.

10. An electrical interface, comprising:
a substrate having a lower surface and an edge surrounds the lower surface; and
an array of thin pins positioned on the lower surface of the substrate, wherein each thin pins comprises a conductive material and is tapered at its lower end that is away from the lower surface of the substrate,
wherein the array of thin pins comprises:
a first thin pin positioned around a center of the lower surface and having a first conical angle at its lower end,
a second thin pin positioned adjacent to edge of the substrate and having a second conical angle at its lower end, the second conical angle is smaller than the first conical angle.

11. The electrical interface of claim 10, wherein the substrate comprises a printed circuit board, wherein at least two of the thin pins are electrically connected to two conductive paths formed in the printed circuit board.

12. The electrical interface of claim 10, wherein the substrate comprises an electrical conductive substrate, and the array of thin pins are electrically connected to the electrical conductive substrate.

13. The electrical interface of claim 10, wherein at least one thin pins extends along a longitudinal axis that is perpendicular to the lower surface of the substrate and comprises a inner portion and a outer portion, wherein the outer portion is located farther away from the longitudinal axis than the inner portion, and the inner portion and the outer portion are formed of different conductive materials.

14. The electrical interface of claim 10, wherein the array of thin pins further comprises a third thin pin positioned between the first thin pin and the second thin pin and has a third conical angle at its lower end, wherein the third conical angle is smaller than the first conical angle but greater than the second conical angle.

15. A processing method, comprising:
moving an array of thin pins into an electrolytic fluid received in an electrolyte tank;
producing measurement data which is related to positions of thin pins in the electrolytic fluid; and
when the measurement data meets a preset standard, applying electrical currents to the array of thin pins and an electrode plate positioned in the electrolyte tank so as to change the shape of each of the thin pins through an electrochemical machining process.

16. The processing method of claim 15, wherein the measurement data is related to a friction force generated between the thin pins and the electrolytic fluid.

17. The processing method of claim 15, wherein the electrical currents are applied in pulse to the array of thin pins.

18. The processing method of claim 15, wherein the electrode plate has multiple processing regions, and the method further comprising inserting the array of thin pins into the processing regions in the electrode plate, wherein different electrical current intensities are applied to the processing regions.

19. The processing method of claim 15, further comprising producing an image of the array of the thin pins to check the geometric shape of the thin pins.

20. The processing method of claim 15, wherein at least one thin pin is formed with two conductive materials having different reduction potentials, wherein the electrical power applied to the at least one thin pin has a voltage greater than the largest reduction potential of the two conductive materials.
